(19) United States
(12) Patent Application Publication
(10) Pub. No.: US 2010/0164118 A1
(43) Pub. Date: Jul. 1, 2010

(54) METHOD FOR FABRICATING SEMICONDUCTOR DEVICE INCLUDING METAL CONTACT

(76) Inventors: Baek-Mann Kim, Gyeonggi-do (KR); Seung-Jin Yeom, Gyeonggi-do (KR); Jik-Ho Cho, Gyeonggi-do (KR)

Correspondence Address: IP & T Law Firm PLC, 7700 Little River Turnpike, Suite 207, Annandale, VA, 22003, US

(21) Appl. No.: 12/483,558

(22) Filed: Jun. 12, 2009

(30) Foreign Application Priority Data
Dec. 29, 2008 (KR) 10-2008-0135791

(51) Int. Cl. H01L 23/522; H01L 21/60

(52) U.S. Cl. 257/774; 438/121; 29/874; 257/E23.145; 257/E21.506

(57) ABSTRACT

A method for fabricating a semiconductor device includes: forming first landing metal contacts over a substrate; forming a plurality of bit lines over the first landing metal contacts, the bit lines insulated from the first landing metal contacts by an inter-layer insulation layer; forming second landing metal through-hole contacts passing between adjacent bit lines to be coupled to the first landing metal contacts; forming metal contacts over the second landing metal contacts; and forming a metal line over the metal contacts.

### CROSS-REFERENCE TO RELATED APPLICATIONS

The present invention claims priority of Korean patent application number 10-2008-0135791, filed on Dec. 29, 2008, the disclosure of which is incorporated by reference herein in its entirety.

### BACKGROUND OF THE INVENTION

The present invention relates to a method for fabricating a semiconductor device, and more particularly, to a method for fabricating a semiconductor device including a metal contact.

A metal line is configured to input or output electrical signals in a dynamic random access memory (DRAM). The metal line is stacked in multiple layers, from a first metal line M1 up to a third metal line M3, to input electrical signals into a device or output electrical signals from a device.

In such a multiple-layer metal line, a sub-metal line in the lowest layer is typically referred to as a first metal line M1. The first metal line M1 is coupled to a bottom bit line through a metal contact. The metal contact is generally referred to as a metal 1 contact (M1C).

A contact etch process is performed to form the metal contact M1C. This process is referred to as a M1C etch process. The M1C etch process is generally performed to form a deep contact hole. Typically, the M1C etch process includes etching an inter-layer insulation layer formed over a bit line to form a contact hole.

FIG. 1 illustrates a cross-sectional view of a typical method for forming a metal line in a peripheral region. FIGS. 2A and 2B illustrate plan views of a typical bit line.

Referring to FIG. 1, a gate structure 12 is formed over a silicon substrate 11. A first inter-layer insulation layer 13 is formed over the substrate structure. The gate structure 12 includes a stack structure of a gate insulation layer 12A, a gate electrode 12B, and a gate hard mask layer 12C.

The first inter-layer insulation layer 13 is etched to form contact holes. Bit line contacts (BLC) 14 are buried in the contact holes.

Bit lines 15 coupled to the bit line contacts 14 are formed. A second inter-layer insulation layer 16 is formed over the substrate structure. At this time, the second inter-layer insulation layer 16 is formed to a very large thickness in the peripheral region, that is, as high as the height of a capacitor formed in a cell region. The bit lines 15 include a stack structure of a bit line wiring layer 15A and a bit line hard mask layer 15B.

A M1C etch process is performed to etch the second inter-layer insulation layer 16 and the bit line hard mask layers 15B to form contact holes. Metal contacts (M1C) 17 are buried in the contact holes.

A metal line 18 is formed to directly couple the bit line wiring layers 15A and the metal line 18 through the metal contacts 17.

In a 30 nm level DRAM, the height of a capacitor becomes higher to secure a cell capacitance (Cp). Thus, the aspect ratio of the contact holes in which the metal contacts 17 are to be buried also becomes higher. Furthermore, the width of the bit lines 15 at the bottom becomes smaller and thus it becomes difficult to pattern using a typical photolithography technology. Consequently, a double patterning technology (DPT) requiring a great degree of difficulty is generally needed.

Therefore, in order to reduce the degree of difficulty in patterning, typical bit lines formed in an island and irregular shape, as shown in FIG. 2A, need to be simplified into bit lines having a line and space structure as shown in FIG. 2B. If the bit lines are formed in the line and space structure, the bit line contacts 14 having an island shape, formed for directly coupling the metal contacts 17 and the bit line wiring layers 15A, may no longer be used in the typical method.

In other words, forming bit lines in a line and space structure means that the typical interconnections which existed between the metal line 18 and the metal contacts 17, between the metal contacts 17 and the bit line wiring layers 15A, between the bit line wiring layers 15A and the bit line contacts 14, and between the bit line contacts 14 and the substrate 11 need to be changed into a structure which includes interconnections between the metal line 18 and the metal contacts 17, and the metal contacts 17 and the substrate 11.

In a DRAM of 30 nm level or greater, it is almost impossible to directly couple a metal contact M1C with a silicon substrate.

FIG. 3 illustrates a cross-sectional view showing limitations which often occur in the typical method. The same or like reference numerals in FIGS. 1 and 3 represent the same or like elements.

Referring to FIG. 3, when a metal contact and a silicon substrate are directly coupled, a contact-not-open event, where a contact hole is not opened over a silicon substrate during a M1C etch process, may occur due to a very large aspect ratio of a contact hole in which a metal contact is to be buried (refer to reference denotation ‘A’).

Furthermore, a bridge (refer to reference denotation ‘B’) may occur due to a short circuit between a bit line wiring layer and a metal contact when a misalignment occurs during a M1C etch process.

### SUMMARY OF THE INVENTION

Embodiments of the present invention are directed to providing a method for fabricating a semiconductor device, which can prevent a contact-not-open event, where a contact hole is not opened during a metal contact (M1C) etch process, and a bridge which is often generated by a short circuit between a bit line wiring layer and a metal contact.

In accordance with an aspect of the present invention, there is provided a method for fabricating a semiconductor device, including: forming first landing metal contacts over a silicon substrate; forming a plurality of bit lines over the first landing metal contacts, the bit lines insulated from the first landing metal contacts by an inter-layer insulation layer; forming second landing metal contacts passing between adjacent bit lines to be coupled to the first landing metal contacts; forming metal contacts over the second landing metal contacts; and forming a metal line over the metal contacts.

In accordance with another aspect of the present invention, there is provided a method for fabricating a semiconductor device, including: forming first landing metal contacts over a first region of a silicon substrate and forming bit line contacts in a second region of the substrate at substantially the same time, wherein the substrate includes the first region and the second region; forming an inter-layer insulation layer over the substrate structure; forming a plurality of bit lines including first bit lines coupled to the bit line contacts in the second region and second bit lines formed over the inter-layer insulation layer in the first region; forming second landing metal contacts passing between adjacent second bit lines to be coupled to the first landing metal contacts; forming metal contacts over the second landing metal contacts; and forming a metal line over the metal contacts.

In accordance with another aspect of the present invention, there is provided a method for fabricating a semiconductor device, including: forming a first inter-layer insulation layer over a silicon substrate that includes a first region and a second region; forming first landing metal contacts in the first region, the first landing metal contacts passing through the first inter-layer insulation layer to be coupled to the substrate; forming a second inter-layer insulation layer over the substrate structure; etching portions of the second inter-layer insulation layer and the first inter-layer insulation layer in the second region to form bit line contact holes exposing portions of the substrate; forming a plurality of bit lines including first bit lines, also functioning as bit line contacts, buried over the bit line contact holes in the second region and second bit lines formed over the second inter-layer insulation layer in the first region; forming second landing metal contacts passing between adjacent second bit lines to be coupled to the first landing metal contacts; forming metal contacts over the second landing metal contacts; and forming a metal line over the metal contacts.

In accordance with another aspect of the present invention, there is provided a semiconductor device having metal contacts coupling a silicon substrate and a metal line, including: landing metal contacts coupling the metal contacts and the substrate.

In accordance with another aspect of the present invention, there is provided a semiconductor device, including: a silicon substrate containing a first region and a second region, wherein a plurality of first bit lines patterned in a line and space form are formed in the first region and a plurality of second bit lines patterned in an irregular form are formed in the second region; gate structures formed in the first region and the second region over the substrate; first landing metal contacts coupled to the gate structures; second landing metal contacts passing between adjacent first bit lines to be coupled to the first landing metal contacts; bit line contacts coupling the second bit lines and the first landing metal contacts; metal contacts including first metal contacts formed over the second landing metal contacts and second metal contacts coupled to the second bit lines; and a metal line coupled to the metal contacts.

### BRIEF DESCRIPTION OF THE DRAWINGS

FIG. 1 illustrates a cross-sectional view of a typical method for forming a metal line in a peripheral region.

FIGS. 2A and 2B illustrate plan views of a typical bit line.

FIG. 3 illustrates a cross-sectional view showing defects which often occur in a typical method.

FIGS. 4A to 4G illustrate cross-sectional views of a method for fabricating a semiconductor device in accordance with a first embodiment of the present invention.

FIGS. 5A to 5G illustrate cross-sectional views of a method for fabricating a semiconductor device in accordance with a second embodiment of the present invention.

FIGS. 6A to 6H illustrate cross-sectional views of a method for fabricating a semiconductor device in accordance with a third embodiment of the present invention.

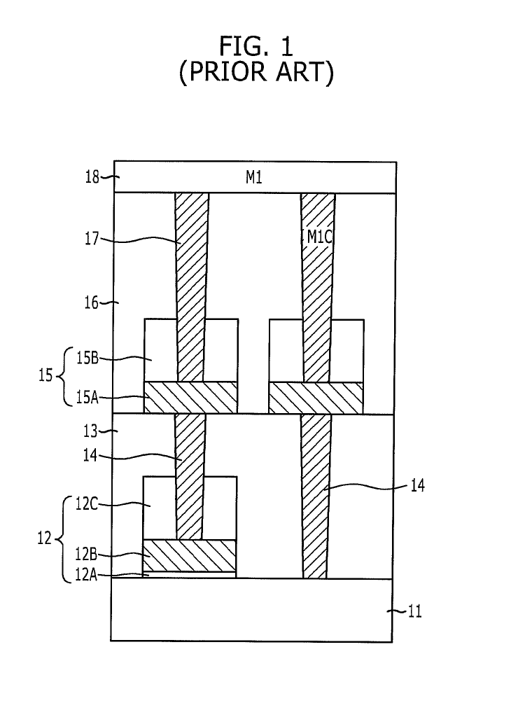

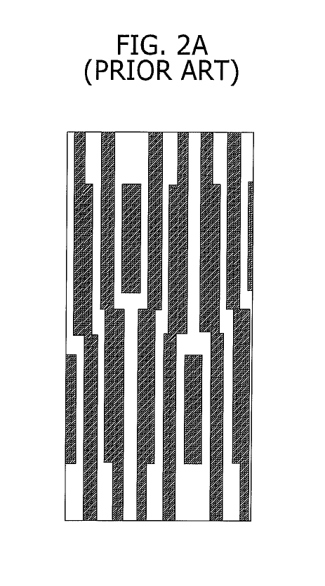

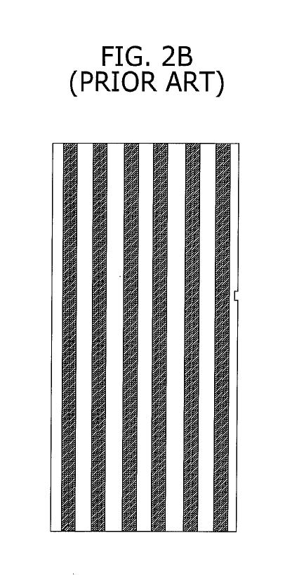

### DESCRIPTION OF SPECIFIC EMBODIMENTS

Other objects and advantages of the present invention can be understood by the following description, and become apparent with reference to the embodiments of the present invention.

Embodiments of the present invention relate to a method for fabricating a semiconductor device including a metal contact. In the embodiments of the present invention, a landing metal contact (LMC) is formed below a metal contact (M1C) in advance when fabricating a semiconductor device with bit lines patterned in a line and space form. Thus, a contact-not-open event and a bridge may be prevented during a M1C etch process for forming the metal contact.

Furthermore, the embodiments of the present invention enable bit line and M1C formation processes, which have the highest degree of difficulty in a fabrication process for a dynamic random access memory (DRAM) of 30 nm level or greater.

In detail, the shape of a pattern may be changed in a manner to reduce the degree of difficulty in a photo-exposure process in certain regions of a peripheral region where a highly difficult photo-exposure technology is generally required because of a greatly reduced bit line pitch.

The embodiments of the present invention will be described in detail with reference to the accompanying drawings so that those ordinary persons skilled in the art may be able to embody the present invention with ease

In the embodiments of the present invention, a realistic level of metal contact etch technology is considered while avoiding a highly difficult process which is often required by a structure including a metal contact M1C directly coupled to a silicon substrate in a 30 nm DRAM. Also, the metal contact M1C is formed in a three-layer structure to prevent a bridge between the metal contact M1C and bit lines.

In other words, a first landing metal contact 1 (LMC1) directly coupled to a silicon substrate is formed below bit lines in advance, a second landing metal contact 2 (LMC2) coupled to the first landing metal contact 1 is formed above and between the bit lines, and a metal contact M1C is formed coupled to the second landing metal contact. Herein, the second landing metal contacts are formed as, for example, a through-hole contacts passing between adjacent bit lines to be coupled to the first landing metal contacts. Consequently, interconnection between a silicon substrate and a metal line is secured by the three-layer structure including the first landing metal contact 1, the second landing metal contact 2, and the metal contact M1C.

In the following, the drawings will mainly show a peripheral region of a DRAM.

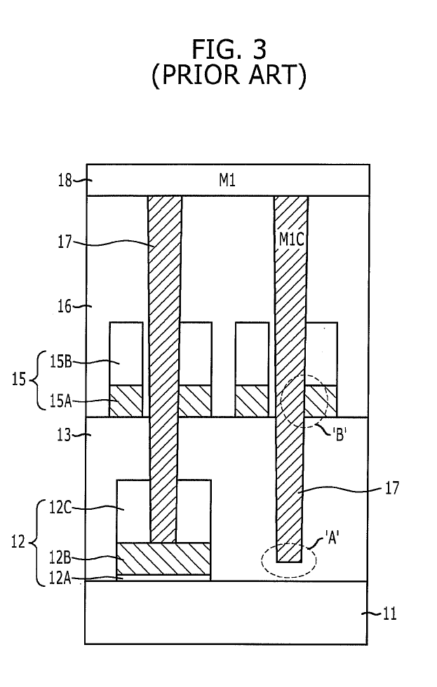

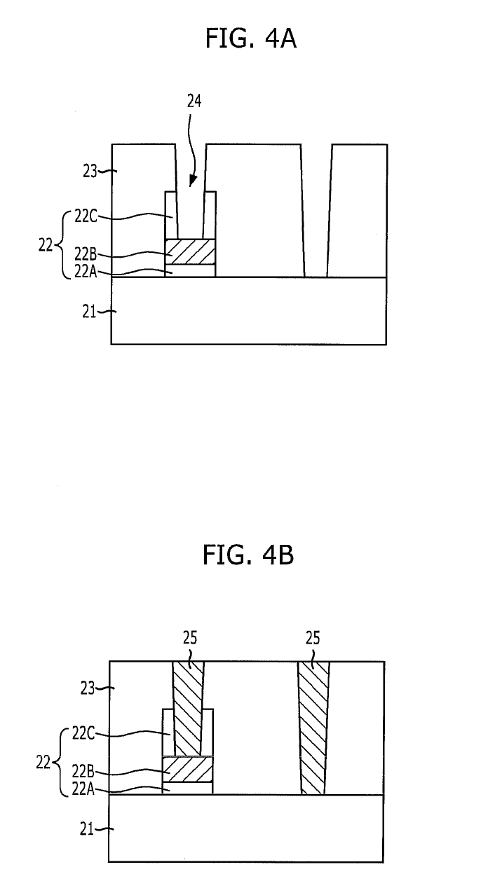

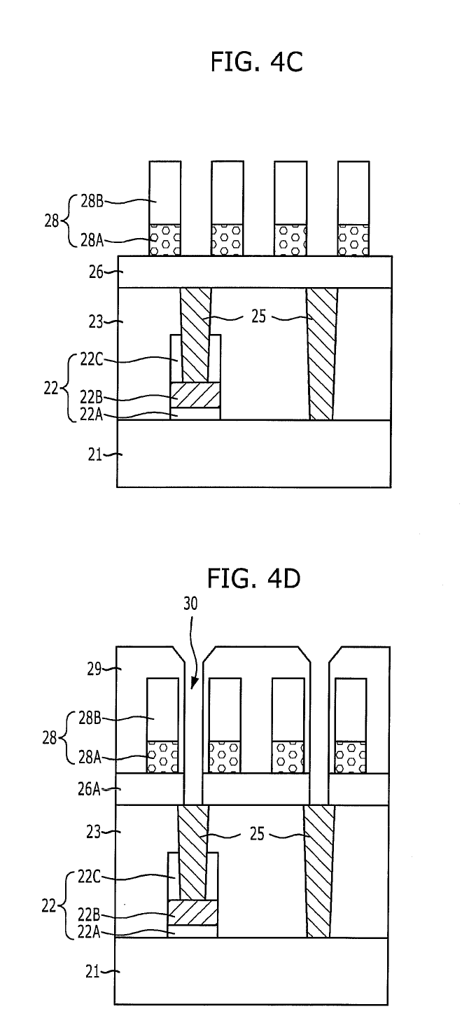

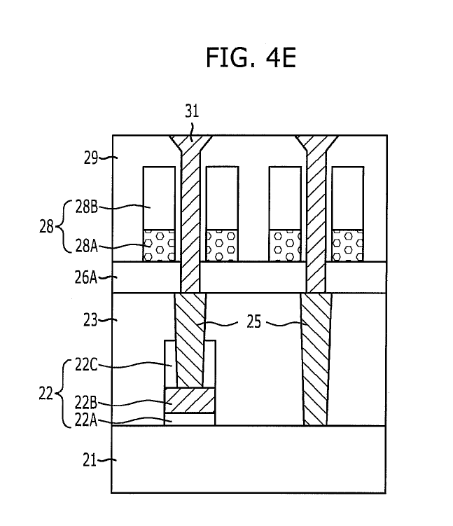

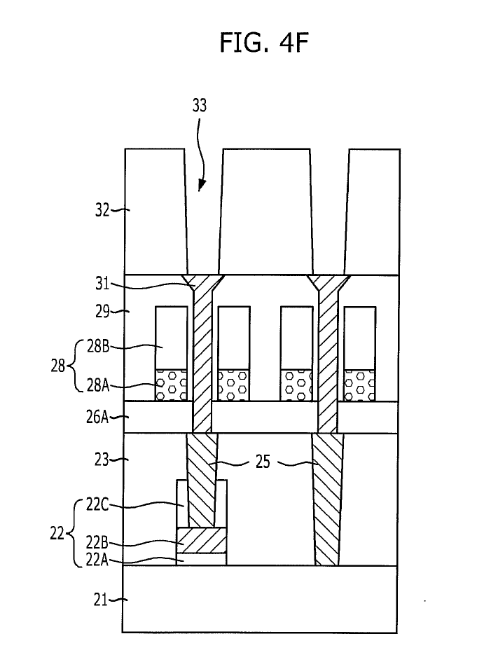

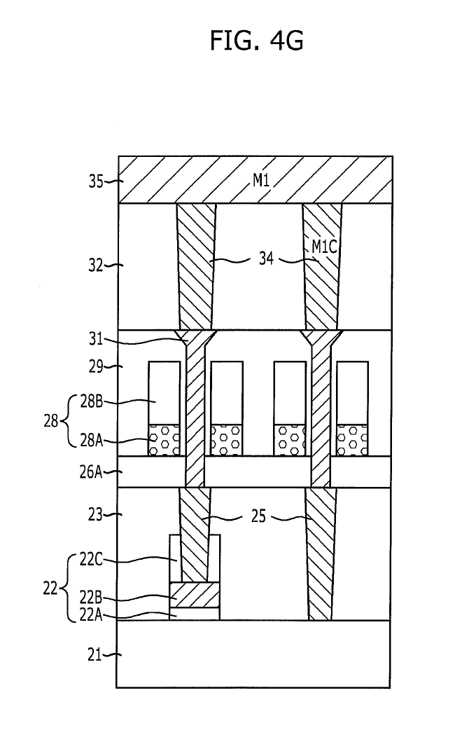

FIGS. 4A to 4G illustrate cross-sectional views of a method for fabricating a semiconductor device in accordance with a first embodiment of the present invention.

Referring to FIG. 4A, a gate stack structure is formed over a silicon substrate 21 in accordance with a typical method for fabricating a DRAM. A first inter-layer insulation layer is formed over the substrate structure. The gate stack structure includes a stack structure of a gate insulation layer 22A, a gate electrode 22B, and a gate hard mask layer. A planarization process may be performed after the first inter-layer insulation layer is formed.

The first inter-layer insulation layer is etched to form first landing contact holes 24. Consequently, a gate structure 22 including a stack structure of the gate insulation layer 22A, the gate electrode 22B, and a gate hard mask 22C is formed. Reference denotation 23 represents a first inter-layer insulation pattern 23.

The first landing contact holes 24 are contact holes in which subsequent first landing metal contacts are to be buried. The first landing contact holes 24 may be formed in a manner to expose portions of the substrate 21 or the gate electrode 22B in the gate structure 22.

A pre-cleaning process is performed to remove any native oxide generated at the bottom of the first landing contact holes 24.

Referring to FIG. 4B, tungsten plugs are buried over the first landing contact holes 24. At this time, the tungsten plugs buried over the first landing contact holes 24 represent first landing metal contacts (LMC1) 25.

The tungsten plugs may be formed as follows.

A typical process for forming ohmic contacts is performed. Titanium silicide, cobalt silicide, nickel silicide, or tungsten silicide is formed over an interface coupled to the substrate 21 to form the ohmic contacts.

A tungsten layer is formed, for instance, using a chemical vapor deposition (CVD) method, and a chemical mechanical polishing (CMP) process is performed to remove portions of the tungsten layer other than portions of the tungsten layer formed inside the first landing contact holes 24, limiting the tungsten plugs to be formed in a buried form in the first landing contact holes 24.

Consequently, the first landing metal contacts 25 are formed in a manner that the first landing metal contacts 25 pass through the first inter-layer insulation pattern 23 to be coupled to the substrate 21 and the gate structure 22.

Referring to FIG. 4C, a second inter-layer insulation layer 26 is formed over the substrate structure. At this time, a thickness of the second inter-layer insulation layer 26 is controlled in a manner to prevent physical and electrical bridges from occurring between the first landing metal contacts 25 and subsequent bit lines.

Bit lines 28 are formed over the substrate structure.

The bit lines 28 may be formed as follows. A barrier metal is formed, and a tungsten layer is formed over the barrier metal. The barrier metal may include one of titanium (Ti)/titanium nitride (TiN) and TiN. The tungsten layer is formed using a CVD method.

Bit line hard mask layers 28B are formed over the tungsten layer using a nitride-based layer, and a bit line patterning process is performed. The bit line patterning process may include a typical photolithography and etch process. At this time, the bit line patterning process includes patterning in a line and space form to lessen the burden of patterning because the bit line pitch is very small in regions where the first landing metal contacts 25 exist. The patterned tungsten layer represents bit line wiring layers 28A.

Referring to FIG. 4D, a third inter-layer insulation layer is formed over the substrate structure. The third inter-layer insulation layer is planarized using a CMP method.

A typical photolithography and etch process is performed to form second landing contact holes 30. The second landing contact holes 30 are formed in a manner that the first landing metal contacts 25 are exposed below the second landing contact holes 30. In order to form the second landing contact holes 30 in such manner, the etch process for forming the second landing contact holes 30 is performed in a manner that the second landing contact holes 30 pass through between adjacent bit lines 28.

The remaining portions of the third inter-layer insulation layer represent a third inter-layer insulation pattern 29, and reference denotation 26A represents a second inter-layer insulation pattern 26A.

When forming the second landing contact holes 30, upper portions of the second landing contact holes 30 may be enlarged to a funnel-like shape so that an overlap margin with respect to subsequent metal contact holes may be secured. For instance, the funnel-like shaped upper portions may be formed using an argon (Ar) sputtering.

Referring to FIG. 4E, a pre-cleaning process is performed. Tungsten plugs are buried in the second landing contact holes 30 after performing the pre-cleaning process. The tungsten plugs buried in the second landing contact holes 30 represent second landing metal contacts (LMC2) 31.

The tungsten plugs may be formed as follows.

A barrier metal is formed. The barrier metal may include Ti/TiN or TiN. A tungsten layer is formed, for instance, using CVD method, and a CMP process is performed to remove portions of the tungsten layer other than portions of the tungsten layer formed inside the second landing contact holes 30, limiting the tungsten plugs to be formed in a buried form in the second landing contact holes 30.

Consequently, the second landing metal contacts 31 are formed in a manner that the second landing metal contacts 31 pass through the third inter-layer insulation pattern 29 and the second inter-layer insulation pattern 26A to be coupled to the first landing metal contacts 25.

Referring to FIG. 4F, a fourth inter-layer insulation layer is formed over the substrate structure. A typical photolithography and etch process is performed to form metal contact holes 33. Reference denotation 32 represents a fourth inter-layer insulation pattern 32. At this time, the metal contact holes 33 are formed in a manner that the second landing metal contacts 31 are exposed below the metal contact holes 33. An etch process for forming the metal contact holes 33 is substantially the same as a typical M1C etch process.

Referring to FIG. 4G, a pre-cleaning process is performed. Tungsten plugs are buried in the metal contact holes 33 after performing the pre-cleaning process. The tungsten plugs buried in the metal contact holes 33 represent metal contacts (M1C) 34.

The tungsten plugs may be formed as follows.

A barrier metal is formed. The barrier metal may include Ti/TiN or TiN. A tungsten layer is formed, for instance, using CVD method, and a CMP process is performed to remove portions of the tungsten layer other than portions of the tungsten layer formed inside the metal contact holes 33, limiting the tungsten plugs to be formed in a buried form in the metal contact holes 33.

Consequently, the metal contacts 34 are formed in a manner that the metal contacts 34 pass through the fourth inter-layer insulation pattern 32 to be coupled to the second landing metal contacts 31.

A metal line (M1) 35 is formed according to a typical DRAM fabrication method.

According to the first embodiment of the present invention, interconnections between the metal line 35 and the metal contacts 34 and between the metal contacts 34 and the substrate 21 are formed in regions where the bit lines 28 are patterned in a line and space form.

In particular, the interconnection between the metal contacts 34 and the substrate 21 is secured by the first landing metal contacts 25 and the second landing metal contacts 31. Thus, it may be possible to interconnect a metal contact (M1C) and a silicon substrate in a DRAM of 30 nm level or greater.

Furthermore, using the first landing metal contacts 25 and the second landing metal contacts 31 reduces an aspect ratio of the metal contact holes 33 in which the metal contacts 34 are to be buried. Consequently, a contact-not-open event or short-circuit between bit line wiring layers and metal contacts may be prevented during a M1C etch process.

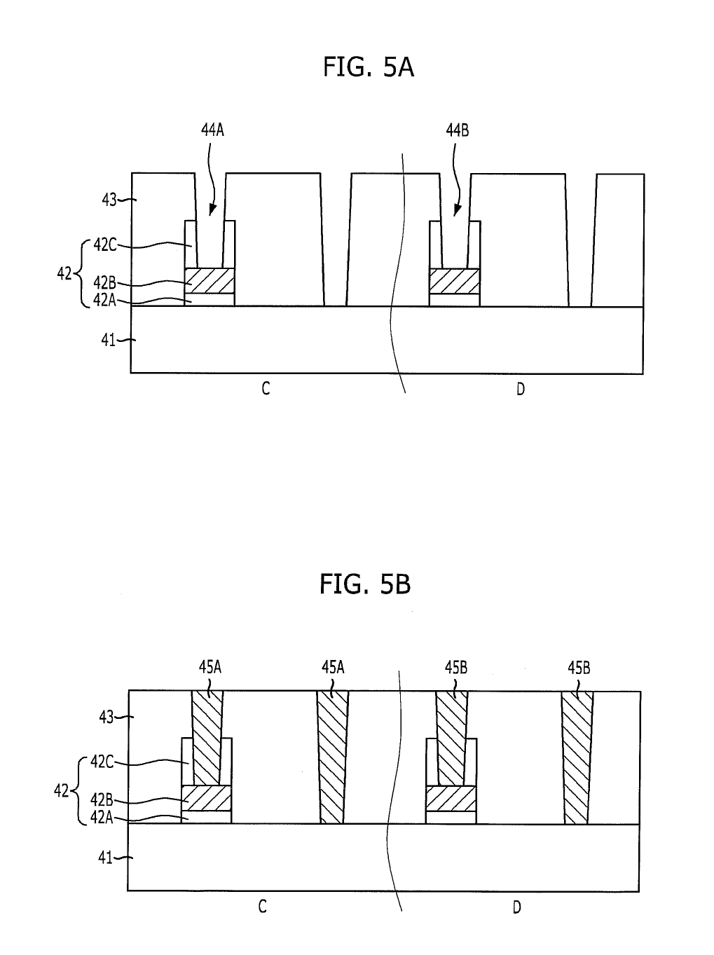

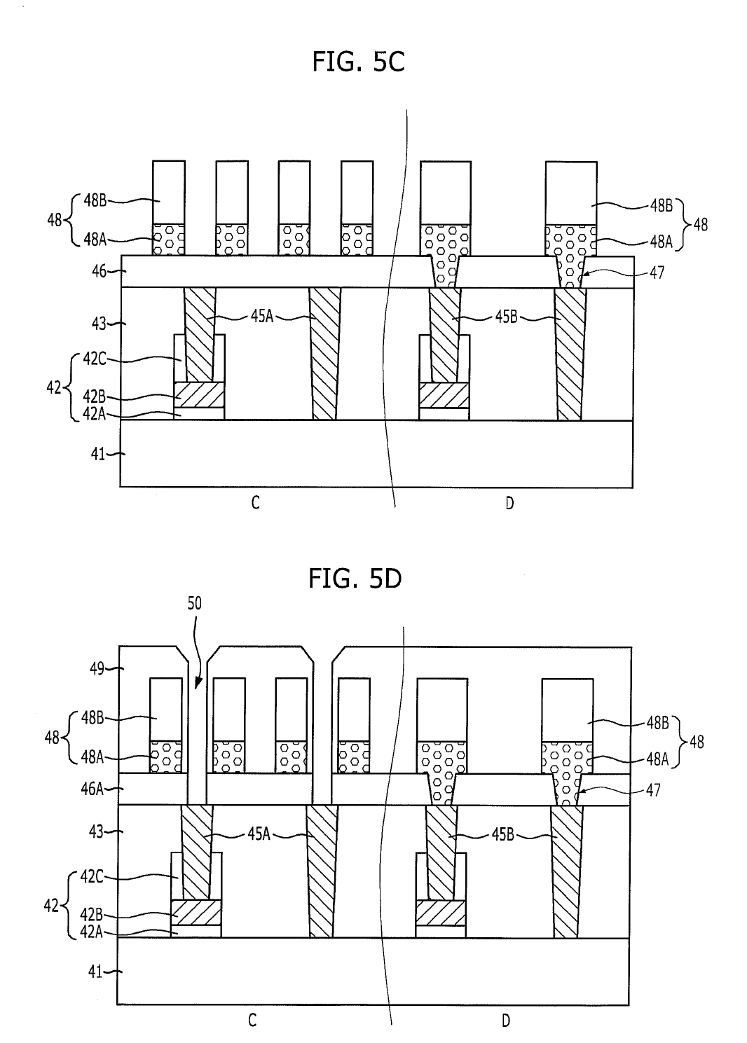

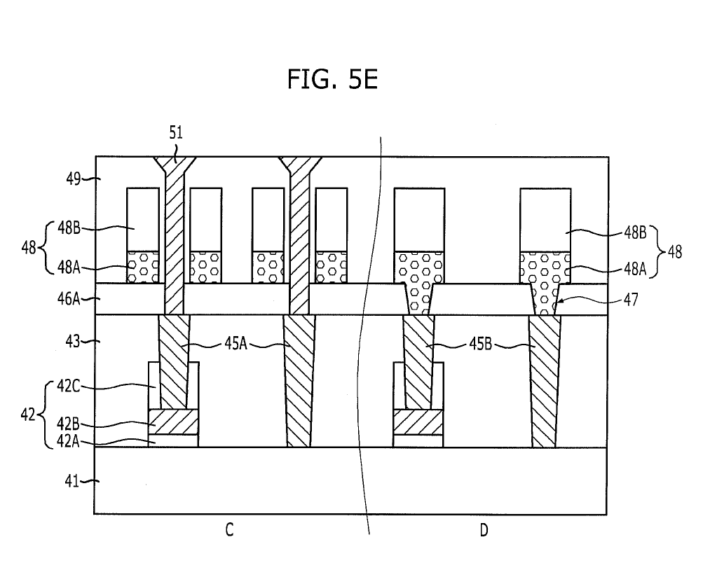

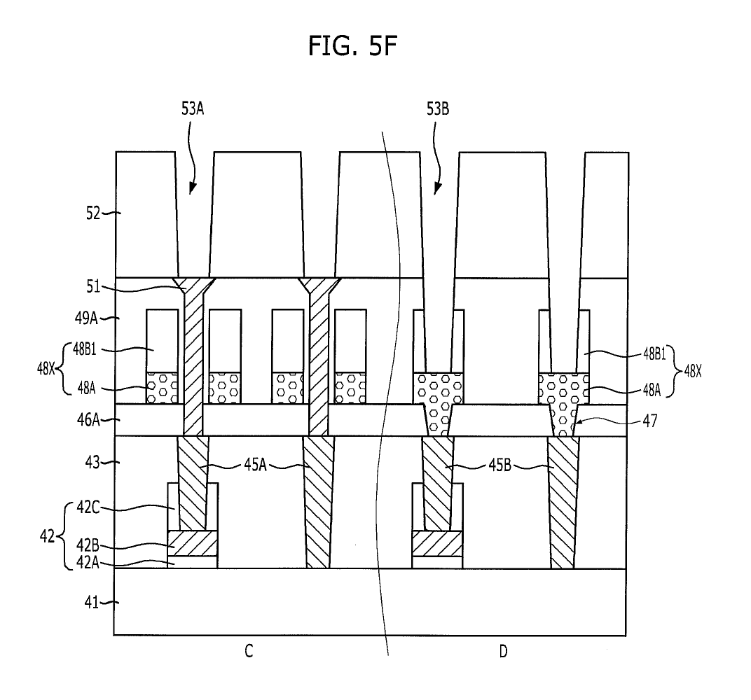

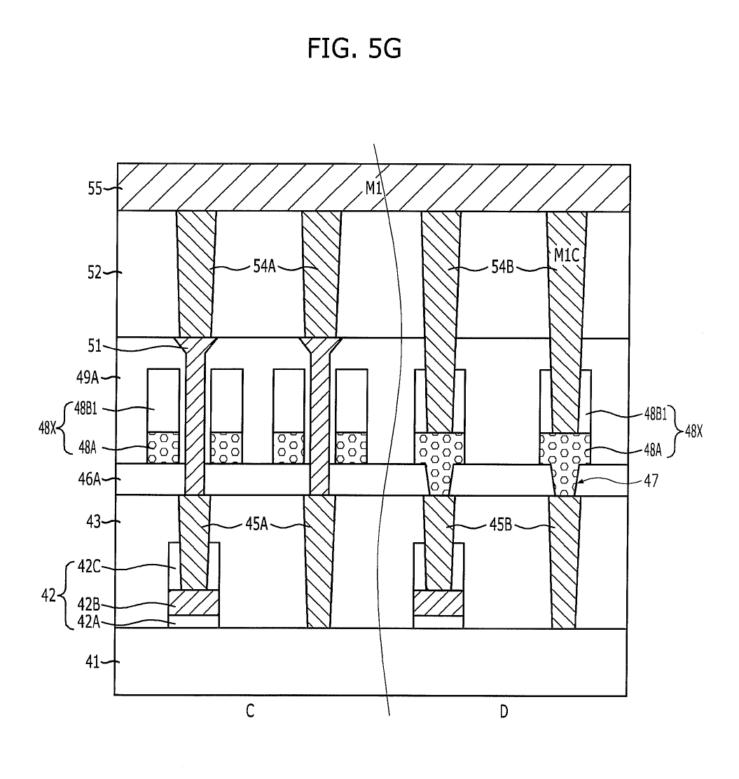

FIGS. 5A to 5G illustrate cross-sectional views of a method for fabricating a semiconductor device in accordance with a second embodiment of the present invention.

Referring to FIG. 5A, gate stack structures are formed over a silicon substrate 41 in accordance with a typical method for fabricating a DRAM. A first inter-layer insulation layer is formed over the substrate structure. The gate stack structures include a stack structure of a gate insulation layer 42A, a gate electrode 42B, and a gate hard mask layer. A planarization process may be performed after the first inter-layer insulation layer is formed.

The substrate 41 may be divided into two regions, i.e., a first region C and a second region D. The first region C is a region where bit lines are patterned in a line and space form, and the second region D is a region where bit lines are patterned in an irregular and island form. In other words, the second embodiment of the present invention shows a fabrication method where bit lines patterned in a line and space form and bit lines patterned in an irregular and island form both exist.

The first inter-layer insulation layer is etched to form first landing contact holes 44A and first bit line contact holes 44B. Consequently, gate structures 42 including a stack structure of the gate insulation layer 42A, the gate electrode 42B, and a gate hard mask 42C are formed. Reference denotation 43 represents a first inter-layer insulation pattern 43. The first landing contact holes 44A are contact holes in which subsequent first landing metal contacts are to be formed, and the first bit line contact holes 44B are contact holes in which subsequent first bit line contacts are to be formed. The first landing contact holes 44A and the first bit line contact holes 44B both may be formed to expose portions of the substrate 41 or the gate electrode 42B.

A pre-cleaning process is performed to remove any native oxide generated at the bottom of the first landing contact holes 44A and the first bit line contact holes 44B.

Referring to FIG. 5B, tungsten plugs are formed, buried in the first landing contact holes 44A and the first bit line contact holes 44B. At this time, the tungsten plugs buried in the first landing contact holes 44A become first landing metal contacts (LMC1) 45A, and other tungsten plugs buried in the first bit line contact holes 44B become first bit line contacts (BLC1) 45B. In other words, the first landing metal contacts 45A are formed in the first region C, and the first bit line contacts 45B are formed in the second region D.

The tungsten plugs for forming the first landing metal contacts 45A and the first bit line contacts 45B may be formed as follows.

A typical process for forming ohmic contacts is performed. Titanium silicide, cobalt silicide, nickel silicide, or tungsten silicide is formed over an interface coupled to the substrate 41 to form the ohmic contacts.

A tungsten layer is formed, for instance, using a chemical vapor deposition (CVD) method, and a chemical mechanical polishing (CMP) process is performed to remove portions of the tungsten layer other than portions of the tungsten layer formed inside the first landing contact holes 44A and the first bit line contact holes 44B, limiting the tungsten plugs to be formed in a buried form in the first landing contact holes 44A and the first bit line contact holes 44B.

Consequently, the first landing metal contacts 45A and the first bit line contacts 45B are formed in a manner that the first landing metal contacts 45A and the first bit line contacts 45B pass through the first inter-layer insulation pattern 43 to be coupled to the substrate 41 and the gate structures 42.

Referring to FIG. 5C, a second inter-layer insulation layer is formed over the substrate structure. At this time, a thickness of the second inter-layer insulation layer is controlled in a manner to prevent physical and electrical bridges from occurring between the first landing metal contacts 45A and subsequent bit lines.

Second bit line contact holes 47 are formed by performing a typical photolithography and etch process. A pre-cleaning is performed after performing the photolithography and etch process. The first bit line contacts 45B are exposed below the second bit line contact holes 47.

The second bit line contact holes 47 are not formed in the first region C. Reference denotation 46 represents a second inter-layer insulation pattern 46.

Bit lines 48 are formed over the substrate structure.

The bit lines 48 may be formed as follows.

A barrier metal is formed. A tungsten layer is formed over the barrier metal, buried in the second bit line contact holes 47. The barrier metal may include titanium (Ti)/titanium nitride (TiN) or TiN. The tungsten layer is formed using a CVD method. Bit line hard mask layers 48B are formed over the tungsten layer using a nitride-based layer, and a bit line patterning process is performed. The patterned tungsten layer represents bit line wiring layers 48A which may also be referred to as second bit line contacts.

The bit line patterning process may include a typical photolithography and etch process. At this time, the bit line patterning process includes patterning in a line and space form to lessen the burden of patterning in the first region C because the bit line pitch is very small in the first region C where the first landing metal contacts 45A are formed. On the other hand, the bit line patterning process may include patterning in a typical irregular and island form in the second region D because the bit line pitch is relatively large in the second region D where the second bit line contact holes 47 are formed, making patterning less burdensome.

The bit lines 48 may also be formed by removing portions of the tungsten layer formed outside the second bit line contact holes 47 using a CMP process, forming another tungsten layer, for instance, using a physical vapor deposition (PVD) method, and a hard mask layer having an appropriate thickness, and performing a bit line patterning.

Referring to FIG. 5D, a third inter-layer insulation layer is formed over the substrate structure. The third inter-layer insulation layer is planarized using a CMP process.

A typical photolithography and etch process is performed to form second landing contact holes 50 in the first region C. The first landing metal contacts 45A are exposed below the second landing contact holes 50.

In order to form the second landing contact holes 50 in such a manner, the etch process for forming the second landing contact holes 50 is performed to pass through between the bit lines 48 in the first region C. Reference denotations 46A and 49 represent a remaining second inter-layer insulation pattern 46A and a third inter-layer insulation pattern 49, respectively.

When forming the second landing contact holes 50, upper portions of the second landing contact holes 50 may be enlarged to a funnel-like shape so that an overlap margin with respect to subsequent metal contact holes may be secured. For instance, the funnel-like shaped upper portions may be formed using an argon (Ar) sputtering.

Referring to FIG. 5E, a pre-cleaning process is performed. Tungsten plugs are formed after performing the pre-cleaning process, buried in the second landing contact holes 50. At this time, the tungsten plugs buried in the second landing contact holes 50 represent second landing metal contacts (LMC2) 51.

The tungsten plugs for forming the second landing metal contacts 51 may be formed as follows.

A barrier metal is formed. The barrier metal may include Ti/TiN or TiN. A tungsten layer is formed, for instance, using a CVD method, and a CMP process is performed to remove portions of the tungsten layer other than portions of the tungsten layer formed inside the second landing contact holes 50, limiting the tungsten plugs to be formed in a buried form in the second landing contact holes 50.

The second landing metal contacts 51 are formed in a manner that the second landing metal contacts 51 pass through the third inter-layer insulation pattern 49 and the remaining second inter-layer insulation pattern 46A to be coupled to the first landing metal contacts 45A.

Referring to FIG. 5F, a fourth inter-layer insulation layer is formed over the substrate structure. A typical photolithography and etch process is performed to form first metal contact holes 53A and second metal contact holes 53B. Reference denotation 52 represents a fourth inter-layer insulation pattern 52. At this time, the second landing metal contacts 51 are exposed at the bottom of the first metal contact holes 53A in the first region C, and the bit line wiring layers 48A are exposed at the bottom of the second metal contact holes 53B in the second region D.

An etch process for forming the first metal contact holes 53A and the second metal contact holes 53B is substantially the same as a typical M1C etch process.

In the first region C, the fourth inter-layer insulation layer is etched to form the first metal contact holes 53A, and in the second region D, the fourth inter-layer insulation layer and the bit line hard mask layers 48B are etched to form the second metal contact holes 53B. Reference denotations 48B1, 48X, and 49A represent bit line hard masks 48B1, remaining bit lines 48X, and a remaining third inter-layer insulation pattern 49A, respectively.

Referring to FIG. 5G, a pre-cleaning process is performed. Tungsten plugs are buried in the first metal contact holes 53A and the second metal contact holes 53B after performing the pre-cleaning process. At this time, the tungsten plugs buried over the first metal contact holes 53A represent first metal contacts (M1C) 54A, and other tungsten plugs buried over the second metal contact holes 53B represent second metal contacts (M1C) 54B. The first metal contacts 54A are coupled to the second landing metal contacts 51, and the second metal contacts 54B are coupled to the bit line wiring layers 48A.

The tungsten plugs for forming the first metal contacts 54A and the second metal contacts 54B may be formed as follows.

A barrier metal is formed. The barrier metal may include Ti/TiN or TiN. A tungsten layer is formed, for instance, using a CVD method, and a CMP process is performed to remove portions of the tungsten layer other than portions of the tungsten layer formed inside the first metal contact holes 53A and the second metal contact holes 53B, limiting the tungsten plugs to be formed in a buried form in the first metal contact holes 53A and the second metal contact holes 53B.

The first metal contacts 54A are formed in a manner that the first metal contacts 54A pass through the fourth inter-layer insulation pattern 52 to be coupled to the second landing metal contacts 51.

A metal line (M1) 55 is formed according to a typical DRAM fabrication process.

According to the second embodiment of the present invention, interconnections between the metal line 55 and the first metal contacts 54A and between the first metal contacts 54A and the substrate 41 are formed in the first region C where the remaining bit lines 48X are patterned in a line and space form.

In particular, the interconnection between the first metal contacts 54A and the substrate 41 is secured by the first landing metal contacts 45A and the second landing metal contacts 51. Consequently, it may be possible to interconnect a metal contact (M1C) and a silicon substrate in a DRAM of 30 nm level or greater.

Furthermore, using the first landing metal contacts 45A and the second landing metal contacts 51 reduces an aspect ratio of the first metal contact holes 53A in which the first metal contacts 54A are to be buried. Consequently, a contact-not-open event or short-circuit between bit line wiring layers and metal contacts may be prevented during a M1C etch process.

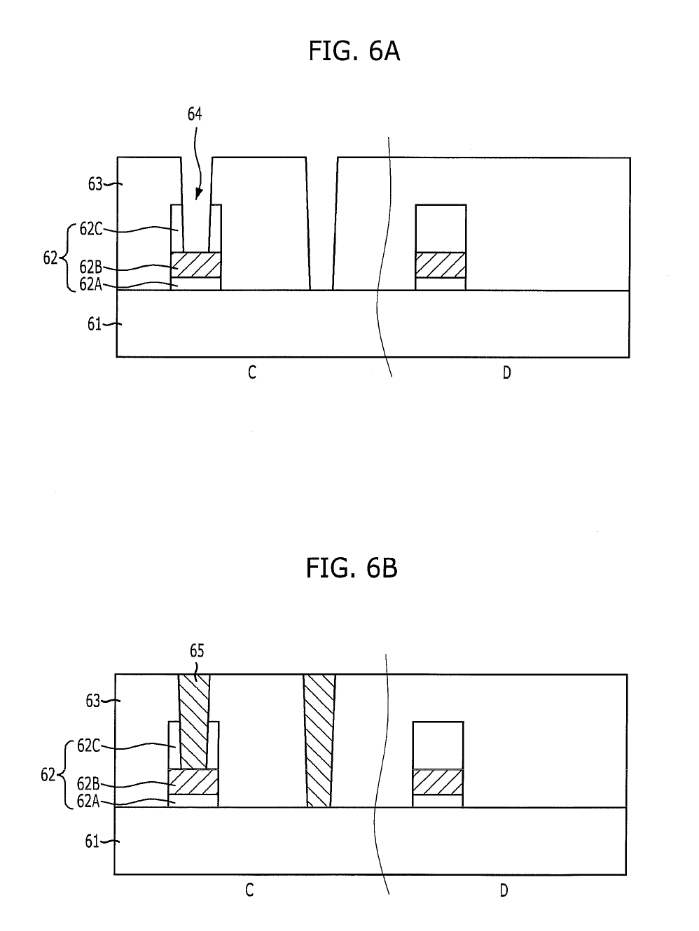

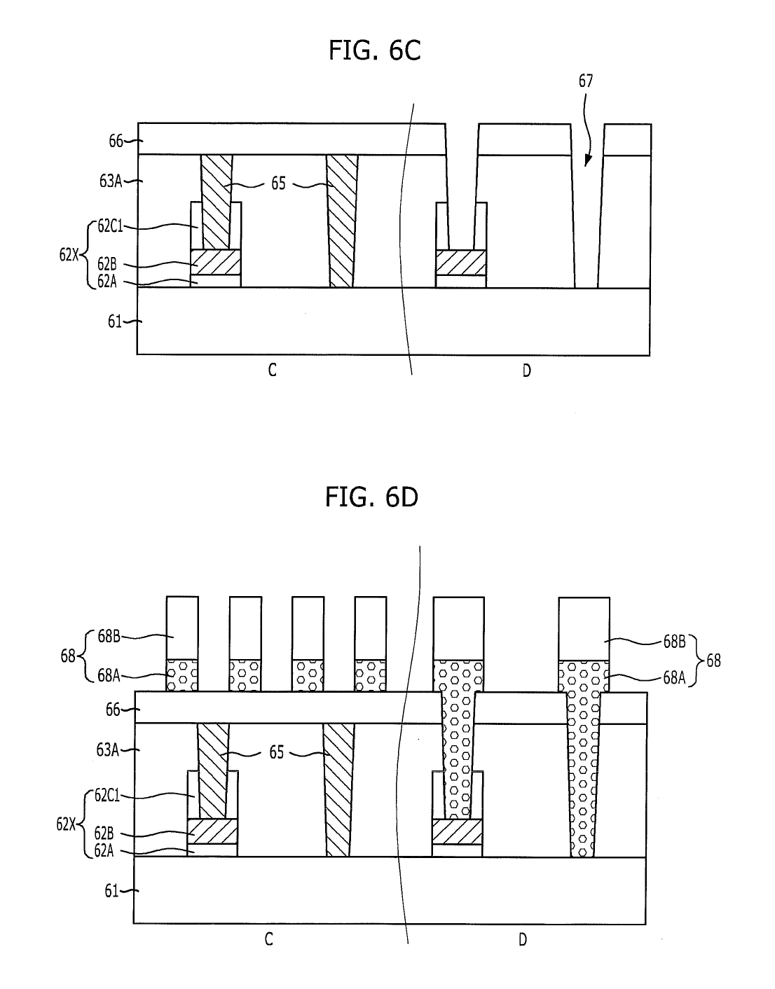

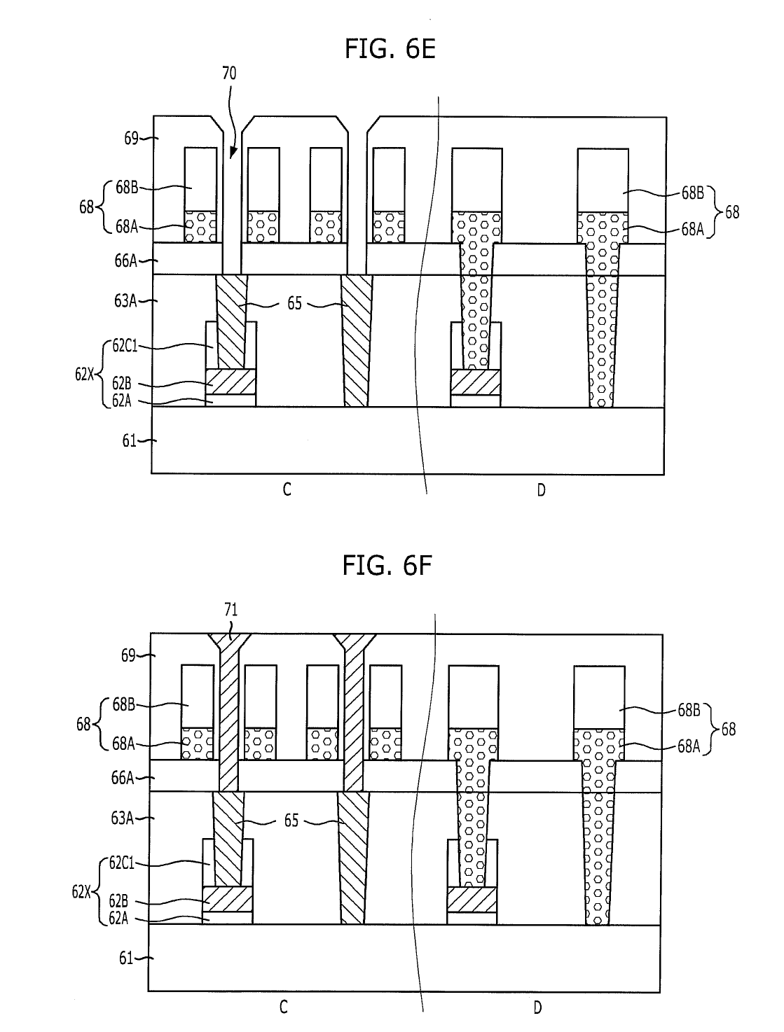

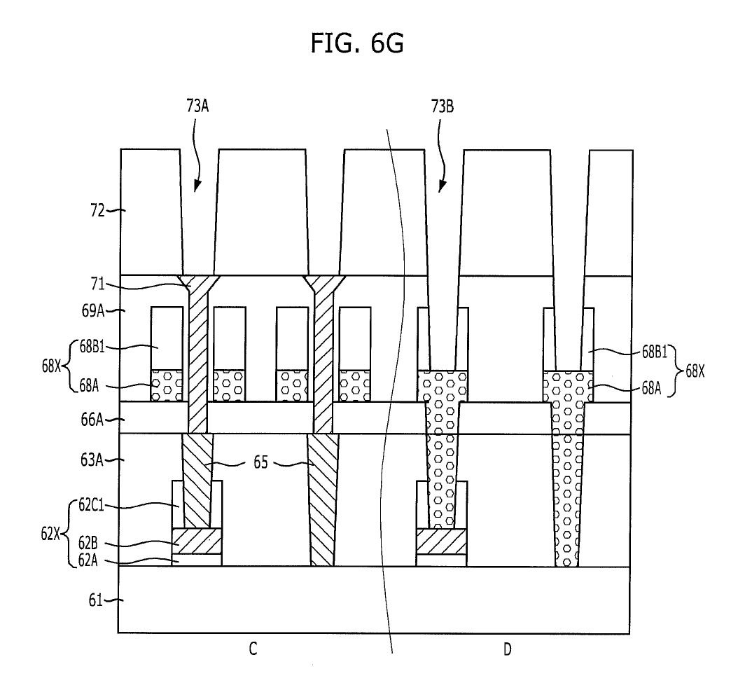

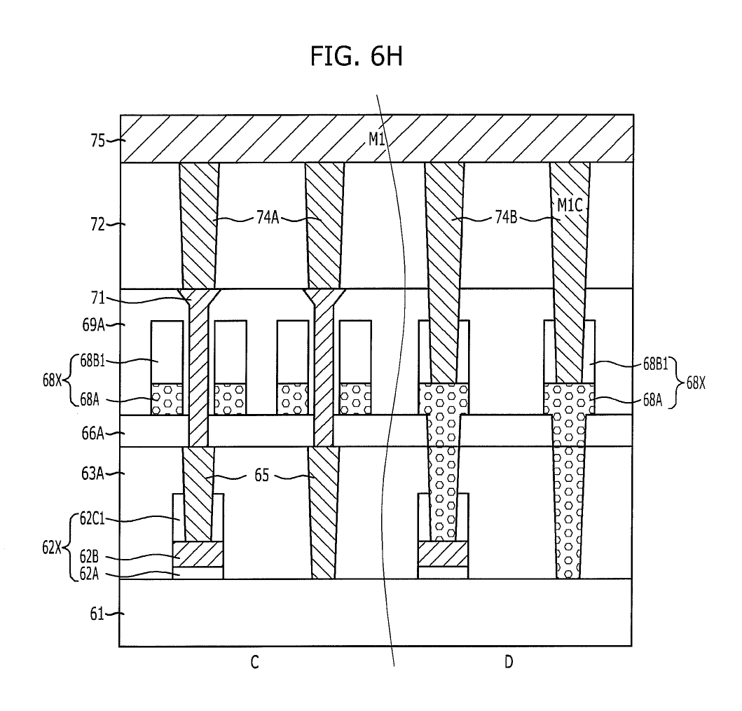

FIGS. 6A to 6H illustrate cross-sectional views of a method for fabricating a semiconductor device in accordance with a third embodiment of the present invention.

Referring to FIG. 6A, gate stack structures are formed over a silicon substrate 61 according to a typical DRAM fabrication method. A first inter-layer insulation layer is formed over the substrate structure. The gate stack structures include a stack structure of a gate insulation layer 62A, a gate electrode 62B, and a gate hard mask layers. A planarization process may be performed after the first inter-layer insulation layer is formed.

The substrate 61 may be divided into two regions, i.e., a first region C and a second region D. The first region C is a region where bit lines are patterned in a line and space form, and the second region D is a region where bit lines are patterned in an irregular and island form. In other words, the third embodiment of the present invention shows a fabrication method where bit lines patterned in a line and space form and bit lines patterned in an irregular and island form both exist.

The first inter-layer insulation layer is etched to form first landing contact holes 64. The first landing contact holes 64 represent contact holes in which subsequent first landing metal contacts are to be formed. The first landing contact holes 64 may be formed in a manner to expose portions of the substrate 61 or the gate electrode 62B. Consequently, gate structures 62 including the gate insulation layer 62A, the gate electrode 62B, and a gate hard mask 62C are formed. Reference denotation 63 represents a first inter-layer insulation pattern 63.

A pre-cleaning process is performed to remove any native oxide generated at the bottom of the first landing contact holes 64.

Referring to FIG. 6B, tungsten plugs are formed, buried in the first landing contact holes 64. At this time, the tungsten plugs buried in the first landing contact holes 64 represent first landing metal contacts (LMC1) 65.

The tungsten plugs for forming the first landing metal contacts 65 may be formed as follows.

A typical process for forming ohmic contacts is performed. Titanium silicide, cobalt silicide, nickel silicide, or tungsten silicide is formed over an interface coupled to the substrate 61 to form the ohmic contacts.

A tungsten layer is formed, for instance, using a chemical vapor deposition (CVD) method, and a chemical mechanical polishing (CMP) process is performed to remove portions of the tungsten layer other than portions of the tungsten layer formed inside the first landing contact holes 64, limiting the tungsten plugs to be formed in a buried form in the first landing contact holes 64.

Consequently, the first landing metal contacts 65 are formed in a manner that the first landing metal contacts 65 pass through the first inter-layer insulation pattern 63 to be coupled to the substrate 61 and the gate structure 62.

Referring to FIG. 6C, a second inter-layer insulation layer is formed over the substrate structure. At this time, a thickness of the second inter-layer insulation layer is controlled in a manner to prevent physical and electrical bridges from occurring between the first landing metal contacts 65 and subsequent bit lines.

A typical photolithography and etch process is performed to form bit line contact holes 67 in the second region D. A pre-cleaning process is performed. The bit line contact holes 67 may be formed to expose portions of the substrate 61 or the gate electrode 62B. Reference denotations 62C1, 62X, 63A, and 66 represent remaining gate hard masks 62C1, remaining gate structures 62X, a remaining first inter-layer insulation pattern 63A, and a second inter-layer insulation pattern 66, respectively.

The bit line contact holes 67 are not formed in the first region C.

Referring to FIG. 6D, bit line contacts and bit lines 68 are formed, buried in the bit line contact holes 67.

A typical process for forming ohmic contacts is performed. Titanium silicide, cobalt silicide, nickel silicide, or tungsten silicide is formed over an interface coupled to the substrate 61 to form the ohmic contacts.

A barrier metal and a tungsten layer are formed, buried over the bit line contact holes 67. The tungsten layer is formed using a CVD method. Bit line hard mask layers 68B are formed over the tungsten layer using a nitride-based layer, and a bit line patterning process is performed. The patterned tungsten layer represents bit line wiring layers 68A which may also be referred to as bit line contacts.

The bit line patterning process may include a typical photolithography and etch process. At this time, the bit line patterning process includes patterning in a line and space form to lessen the burden of patterning in the first region C because the bit line pitch is very small in the first region C where the first landing metal contacts 65 are formed. On the other hand, the bit line patterning process may include patterning in a typical irregular and island form in the second region D because the bit line pitch is relatively large in the second region D where the bit line contact holes 67 are formed, making the burden of patterning less severe.

The bit lines 68 may also be formed by removing portions of the tungsten layer formed outside the bit line contact holes 67 using a CMP process, forming another tungsten layer, for instance, using a physical vapor deposition (PVD) method, and a hard mask layer having an appropriate thickness, and performing a bit line patterning.

Referring to FIG. 6E, a third inter-layer insulation layer is formed over the substrate structure. A CMP process is performed to planarize the third inter-layer insulation layer.

A typical photolithography and etch process is performed to form second landing contact holes 70 in the first region C. The first landing metal contacts 65 are exposed at the bottom of the second landing contact holes 70. In order to form the second landing contact holes 70 in such a manner, the etch process for forming the second landing contact holes 70 is performed to pass through between the bit lines 68. Reference denotations 66A and 69 represent a remaining second inter-layer insulation pattern 66A and a third inter-layer insulation pattern 69, respectively.

When forming the second landing contact holes 70, upper portions of the second landing contact holes 70 may be enlarged to a funnel-like shape so that an overlap margin with respect to subsequent metal contact holes may be secured. For instance, the funnel-like shaped upper portions may be formed using an argon (Ar) sputtering.

Referring to FIG. 6F, a pre-cleaning process is performed. Tungsten plugs are formed after performing the pre-cleaning process, buried in the second landing contact holes 70. At this time, the tungsten plugs buried in the second landing contact holes 70 represent second landing metal contacts (LMC2) 71.

The tungsten plugs for forming the second landing metal contacts 71 may be formed as follows.

A barrier metal is formed. The barrier metal may include titanium (Ti)/titanium nitride (TiN) or TiN. A tungsten layer is formed, for instance, using a CVD method, and a CMP process is performed to remove portions of the tungsten layer other than portions of the tungsten layer formed inside the second landing contact holes 70, limiting the tungsten plugs to be formed in a buried form in the second landing contact holes 70.

The second landing metal contacts 71 are formed in a manner that the second landing metal contacts 71 pass through the third inter-layer insulation pattern 69 and the remaining second inter-layer insulation pattern 66A to be coupled to the first landing metal contacts 65.

Referring to FIG. 6G, a fourth inter-layer insulation layer is formed over the substrate structure. A typical photolithography and etch process is performed to form first metal contact holes 73A and second metal contact holes 73B. Reference denotation 72 represents a fourth inter-layer insulation pattern 72. At this time, the second landing metal contacts 71 are exposed at the bottom of the first metal contact holes 73A in the first region C, and the bit line wiring layers 68A are exposed at the bottom of the second metal contact holes 73B in the second region D. An etch process for forming the first metal contact holes 73A and the second metal contact holes 73B is substantially the same as a typical M1C etch process.

The fourth inter-layer insulation layer is etched to form the first metal contact holes 73A in the first region C, and the fourth inter-layer insulation layer and the bit line hard mask layers 68B are etched to form the second metal contact holes 73B in the second region D. Reference denotations 68B1, 68X, and 69A represent bit line hard masks 68B1, remaining bit lines 68X, and a remaining third inter-layer insulation pattern 69A, respectively.

Referring to FIG. 6H, a pre-cleaning process is performed. Tungsten plugs are formed after performing the pre-cleaning process, buried in the first metal contact holes 73A and the second metal contact holes 73B. At this time, the tungsten plugs buried over the first metal contact holes 73A and the second metal contact holes 73B represent first metal contacts (M1C) 74A and second metal contacts (M1C) 74B. The first metal contacts 74A are coupled to the second landing metal contacts 71, and the second metal contacts 74B are coupled to the bit line wiring layers 68A.

The tungsten plugs may be formed as follows.

A barrier metal is formed. The barrier metal may include Ti/TiN or TiN. A tungsten layer is formed, for instance, using a CVD method, and a CMP process is performed to remove portions of the tungsten layer other than portions of the tungsten layer formed inside the first metal contact holes 73A and the second metal contact holes 73B, limiting the tungsten plugs to be formed in a buried form in the first metal contact holes 73A and the second metal contact holes 73B.

The first metal contacts 74A are formed in a manner that the first metal contacts 74A pass through the fourth inter-layer insulation pattern 72 to be coupled to the second landing metal contacts 71.

A metal line (M1) 75 is formed according to a typical DRAM fabrication process.

According to the third embodiment of the present invention, interconnections between the metal line 75 and the first metal contacts 74A and between the first metal contacts 74A and the substrate 61 are formed in the first region C where the remaining bit lines 68X are formed in a line and space form.

In particular, the interconnection between the first metal contacts 74A and the substrate 61 is secured by the first landing metal contacts 65 and the second landing metal contacts 71. Consequently, it may be possible to interconnect a metal contact (M1C) and a silicon substrate in a DRAM of 30 nm level or greater.

Furthermore, using the first landing metal contacts 65 and the second landing metal contacts 71 reduces an aspect ratio of the first metal contact holes 73A in which the first metal contacts 74A are to be buried. Consequently, a contact-not-open event or short-circuit between bit line wiring layers and metal contacts may be prevented during a M1C etch process.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
forming first landing metal contacts over a substrate;
forming a plurality of bit lines over the first landing metal contacts, the bit lines insulated from the first landing metal contacts by an inter-layer insulation layer;
forming second landing metal contacts passing between adjacent bit lines to be coupled to the first landing metal contacts;
forming metal contacts over the second landing metal contacts; and
forming a metal line over the metal contacts.

2. The method of claim 1, wherein the forming of the bit lines comprises patterning the bit lines in a line and space form.

3. The method of claim 1, wherein a gate structure is formed over the substrate and the first landing metal contacts are coupled to the gate structure and the substrate, respectively.

4. The method of claim 1, wherein each of said forming of the first and second landing metal contacts comprises forming tungsten plugs.

5. The method of claim 1, wherein ohmic contacts are formed before the forming of the first landing metal contacts.

6. A method for fabricating a semiconductor device, comprising:
forming first landing metal contacts over a first region of a substrate and forming bit line contacts in a second region of the substrate at substantially the same time, wherein the substrate includes the first region and the second region;
forming an inter-layer insulation layer over the substrate structure;
forming a plurality of bit lines including first bit lines coupled to the bit line contacts in the second region and second bit lines formed over the inter-layer insulation layer in the first region;
forming second landing metal through-hole contacts passing between adjacent second bit lines to be coupled to the first landing metal contacts;
forming metal contacts over the second landing metal contacts; and
forming a metal line over the metal contacts.

7. The method of claim 6, wherein the metal contacts are coupled to the first bit lines.

8. The method of claim 6, wherein the second bit lines are patterned in a line and space form and the first bit lines are patterned in an irregular and island form.

9. The method of claim 6, wherein a gate structure is formed over the substrate and the first landing metal contacts are coupled to the gate structure and the substrate.

10. A method for fabricating a semiconductor device, comprising:
forming a first inter-layer insulation layer over a substrate that includes a first region and a second region;
forming first landing metal contacts in the first region, the first landing metal contacts passing through the first inter-layer insulation layer to be coupled to the substrate;
forming a second inter-layer insulation layer over the substrate structure;
etching portions of the second inter-layer insulation layer and the first inter-layer insulation layer in the second region to form bit line contact holes exposing portions of the substrate;
forming a plurality of bit lines including first bit lines, also functioning as bit line contacts, buried over the bit line contact holes in the second region and second bit lines formed over the second inter-layer insulation layer in the first region;
forming second landing metal through hole contacts passing between adjacent second bit lines to be coupled to the first landing metal contacts;
forming metal contacts over the second landing metal contacts; and
forming a metal line over the metal contacts.

11. The method of claim 10, wherein the metal contacts are coupled to the first bit lines.

12. The method of claim 10, wherein the second bit lines are patterned in a line and space form and the first bit lines are patterned in an irregular and island form.

13. The method of claim 10, wherein each of the first landing metal contacts and the second landing metal contacts comprises tungsten plugs.

14. The method of claim 10, wherein ohmic contacts are formed before the forming of the first landing metal contacts.

15. The method of claim 10, wherein a gate structure is formed over the substrate and the first landing metal contacts are coupled to the gate structure and the substrate.

16. A semiconductor device having metal contacts coupling a substrate and a metal line, comprising:
landing metal contacts coupling the metal contacts to the substrate.

17. The semiconductor device of claim 16, wherein the landing metal contacts each comprise a stack structure of a first landing metal contact and a second landing metal contact.

18. The semiconductor device of claim 17, wherein upper portions of landing contact holes to be buried by the second landing metal contacts are each enlarged in a funnel-like shape.

19. The semiconductor device of claim 17, wherein the second landing metal through-hole contact passes between bit lines patterned in a line and space form.

20. The semiconductor device of claim 17, wherein the first landing metal contact is coupled to a gate structure and the substrate.

21. A semiconductor device, comprising:
a substrate including a first region and a second region, wherein a plurality of first bit lines patterned in a line and space form are formed in the first region and a plurality of second bit lines patterned in an irregular and island form are formed in the second region;
gate structures formed in the first region and the second region over the substrate;
first landing metal contacts coupled to the gate structures;
second landing metal through-hole contacts passing between adjacent first bit lines to be coupled to the first landing metal contacts;
bit line contacts coupling the second bit lines and the first landing metal contacts;
metal contacts including first metal contacts formed over the second landing metal contacts and second metal contacts coupled to the second bit lines; and
a metal line coupled to the metal contacts.

22. The semiconductor device of claim 21, further comprising a coupling structure including the first metal contacts, the second landing metal contacts and the first landing metal contacts, wherein the coupling structure couples the metal line and the substrate in the first region.

23. The semiconductor device of claim 21, further comprising a coupling structure including the second metal contacts, the second bit lines, the bit line contacts, and the first landing metal contacts, wherein the coupling structure couples the metal line and the substrate in the second region.
